(19) United States
(12) Patent Application Publication
(10) Pub. No.: US 2010/0265002 A1
(43) Pub. Date: Oct. 21, 2010

(54) METHOD OF MODULATING A COMMON SIGNAL OF LIQUID CRYSTAL DISPLAY

(76) Inventors: Liang-Ming Yu, Taoyuan County (TW); Chao-Hui Hsu, Taoyuan County (TW)

Correspondence Address: NORTH AMERICA INTELLECTUAL PROPERTY CORPORATION, P.O. BOX 506, MERRIFIELD, VA, 22116, US

(21) Appl. No.: 12/496,648

(22) Filed: Jul. 2, 2009

(30) Foreign Application Priority Data
Apr. 17, 2009 (TW) 098112821

(51) Int. Cl. H03C 3/00

(52) U.S. Cl. 332/117

(57) ABSTRACT

A driving circuit of LCD includes a common signal generator and a modulation circuit. The modulation circuit can generate a first frequency, a second frequency, and a third frequency. The common signal generator generates a swing common signal according to the first frequency, and modulates the frequency of the common signal in the frequency range between the second frequency and the third frequency.

### BACKGROUND OF THE INVENTION

1. Field of the Invention

The present invention is related to a method of generating a common signal for an LCD, and more particularly, to a method of modulating the common signal of the LCD.

2. Description of the Prior Art

LCD (Liquid Crystal Display) is a common device utilized in applications such as mobile phones and PDAs (Personal Data Assistants). The mobile phone or the PDA displays images and processes sound signals, so the flicker and the acoustic noise generated by the LCD need to be as low as possible, for avoiding downgrading the display/communication quality of the mobile phone or the PDA.

Please refer to FIG. 1. FIG. 1 is a diagram illustrating the conventional common signal generator of the LCD. The common signal generator 12 of the LCD generates the swing common signal V_{COM} according to a high level voltage V_{COMH}, a low level voltage V_{COML} and a clock signal CLK. The LCD of conventional size utilizes the swing common signal V_{COM}, which carries waveforms of a fixed frequency and a fixed voltage level. Since the swing common signal utilizes AC voltage, the acoustic noise generated when the LCD is operating is related to the common signal V_{COM}. If the resolution of the LCD is QVGA (240*RGB*320), the frequency of the common signal of the LCD can be calculated as below:

Frequency of the common signal≈frame period*160=9.6 kHz, wherein the frame period is usually 60 Hz.

Please refer to FIG. 2. FIG. 2 is a diagram illustrating the time domain and the frequency domain of the common signal V_{COM}. As shown in FIG. 2, the part (A) represents the time domain of the common signal V_{COM}, where the horizontal axis represents the time and the vertical axis represents the frequency; the part (B) represents the frequency domain of the common signal V_{COM}, where the horizontal axis represents the frequency and the vertical axis represents the amplitude (in dB); F_{VCOM} represents the frequency of the common signal. As shown in the time domain of the common signal V_{COM}, the common signal V_{COM} carries the fixed frequency F_{VCOM}, therefore, as illustrated in the frequency domain of the common signal V_{COM}, the energy of the acoustic noise is accumulated in the fixed frequency F_{VCOM}. Similarly, taking the LCD with the resolution of QVGA (240*RGB*320) as an example, the frequency of the corresponding common signal V_{COM} is approximately 9.6 kHz, so the energy of the acoustic noise is accumulated at 9.6 kHz accordingly.

Human can perceive the sound in the frequency range of 20 Hz to 20 kHz, and such range is called the audible range. The human's sensitivity towards noise is depended on the frequency of the noise. The sound between the frequency range of 8 kHz and 12 kHz is especially sensitive to human. The acoustic noise caused by the common signal at the frequency of 9.6 kHz is relatively weak but the user can still detect the interference caused by the acoustic noise when the LCD is placed near the ear. The above mentioned situation is most likely to occur when the user places the mobile phone or PDA close to the ear for making/answering the call, consequently the communication quality is inevitably affected by the acoustic noise generated by the LCD.

### SUMMARY OF THE INVENTION

The present invention provides a method for modulating a common signal of the LCD. The method comprises providing a first frequency; generating a swing common signal according to the first frequency; generating a second frequency and a third frequency according to the first frequency; and modulating a frequency of the common signal in a frequency range between the second frequency and the third frequency.

The present invention further provides a driving circuit of an LCD. The driving circuit comprises a common signal generator, for generating a swing common signal according to a high level voltage and a low level voltage; and a modulation circuit, electrically connected to the common signal generator, for modulating frequency of the common signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating the conventional common signal generator of the LCD.

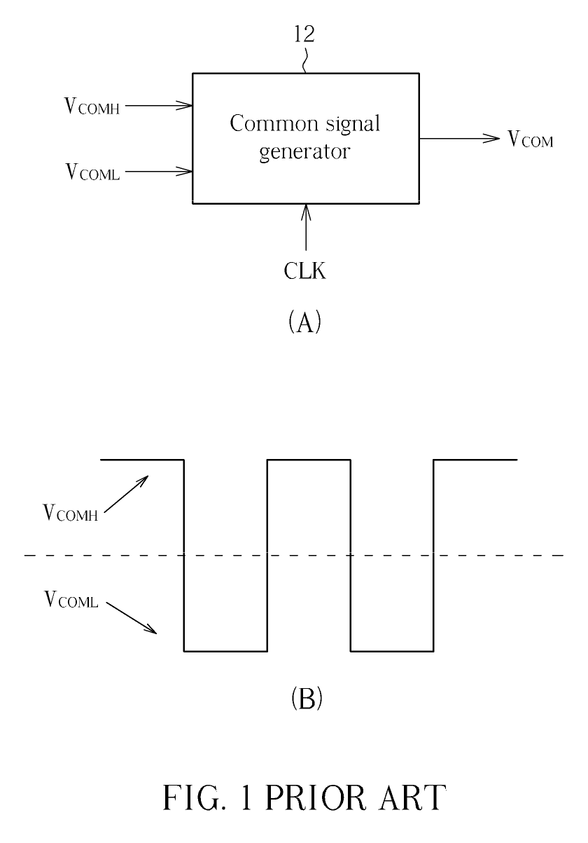

FIG. 2 is a diagram illustrating the time domain and the frequency domain of the common signal.

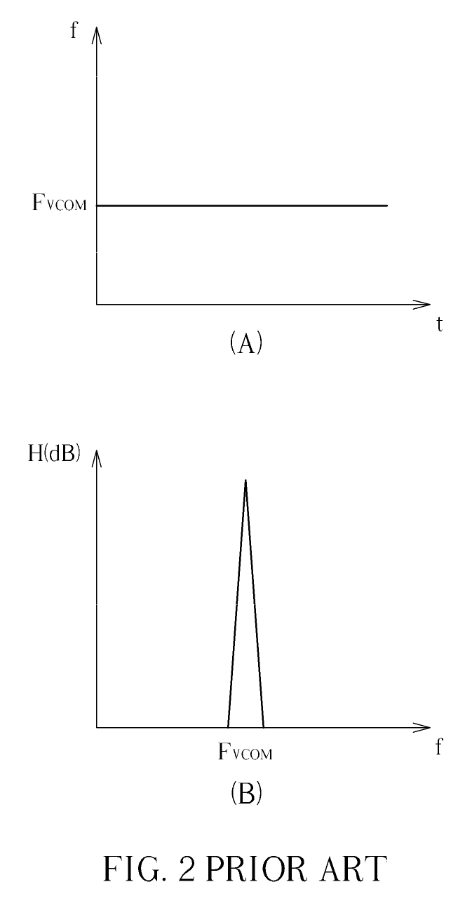

FIG. 3 is a diagram illustrating the driving circuit of the LCD of the present invention.

FIG. 4 is a diagram illustrating the time domain and the frequency domain of the common signal.

### DETAILED DESCRIPTION

Certain terms are used throughout the description and following claims to refer to particular components. As one skilled in the art will appreciate, electronic equipment manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ” Also, the term “electrically connect” is intended to mean either an indirect or direct electrical connection. Accordingly, if one device is coupled to another device, that connection may be through a direct electrical connection, or through an indirect electrical connection via other devices and connections.

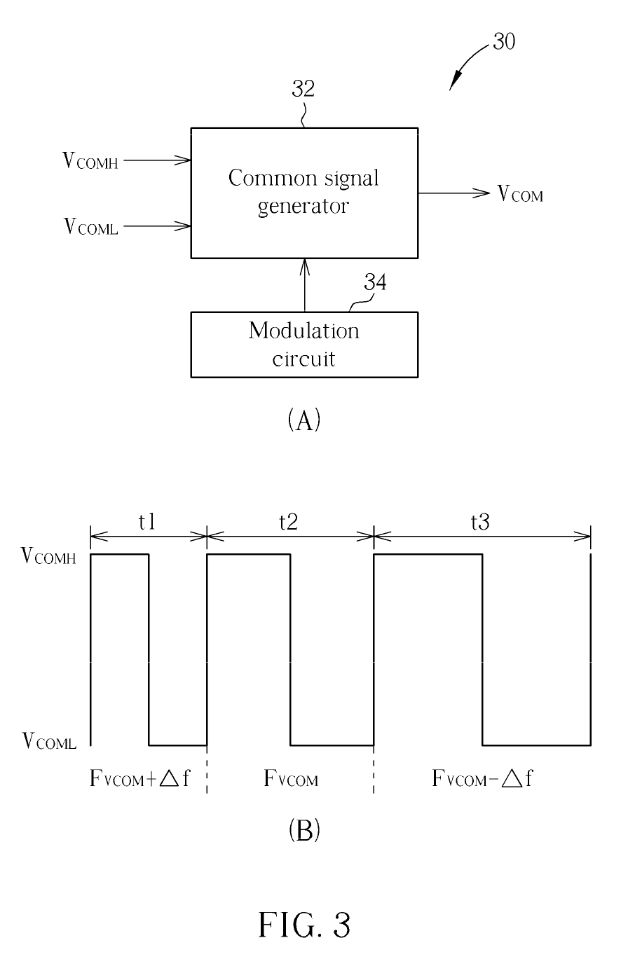

Please refer to FIG. 3. FIG. 3 is a diagram illustrating the driving circuit of the LCD of the present invention. The driving circuit 30 comprises a common signal generator 32 and a modulation circuit 34. The common signal generator 32 generates a swing common signal V_{COM} according to a high level voltage V_{COMH} and a low level voltage V_{COML}. The modulation circuit 34 is utilized to modulate the frequency of the common signal V_{COM}. The LCD outputs the display signal according to the modulated common signal V_{COM}. The modulation circuit 34 provides a first frequency F_{VCOM} and the common signal generator 32 generates the common signal V_{COM} according to the first frequency F_{VCOM}. The modulation circuit 34 then generates a second frequency F_{VCOM}+Δf and a third frequency F_{VCOM}−Δf according to the first frequency F_{VCOM}. The modulation circuit 34 modulates the common signal V_{COM}, which was generated according to the first frequency F_{VCOM}, to a frequency between the second frequency F_{VCOM}+Δf and the third frequency F_{VCOM}−Δf. In a preferred embodiment, the modulation circuit 34 provides the first frequency F_{VCOM}. According to the first frequency F_{VCOM}, the modulation circuit 34 generates the second frequency F_{VCOM}+Δf and the third frequency F_{VCOM}−Δf that are higher and lower than the first frequency F_{VCOM}, respectively. The common signal generator 32 generates the common signal V_{COM} of different frequencies according to the first frequency F_{VCOM} the second frequency F_{VCOM}+Δf and the third frequency F_{VCOM}−Δf. For instances, the common signal generator 32 generates the common signal V_{COM} of the second frequency F_{VCOM}+Δf in the first duration t1, the common signal generator 32 generates the common signal V_{COM} of the first frequency F_{VCOM} in the second duration t2, and the common signal generator 32 generates the common signal V_{COM} of the third frequency F_{VCOM}−Δf in the third duration t3. In addition, the common signal generator 32 can generate the common signal V_{COM} of different frequencies that are between the second frequency F_{VCOM}+Δf and the third frequency F_{VCOM}−Δf.

Human can easily detect the noise generated from the fixed frequency of the common signal V_{COM} generated from the conventional common signal generator. Therefore, by utilizing the modulation circuit 34 of the present invention to generate different frequencies, the common signal generator 32 generates the common signal V_{COM} of different frequencies according to the frequency provided by the modulation circuit 34, for altering the internal resonance of the LCD and consequently reducing the dB value of the noise generated from the single frequency of the prior art. Such method does not alter the current structure or manufacturing process of the LCD. Furthermore, after the frequency of the common signal V_{COM} is modulated, the driving signal of the LCD is required to be modified according to the modulated common signal V_{COM}.

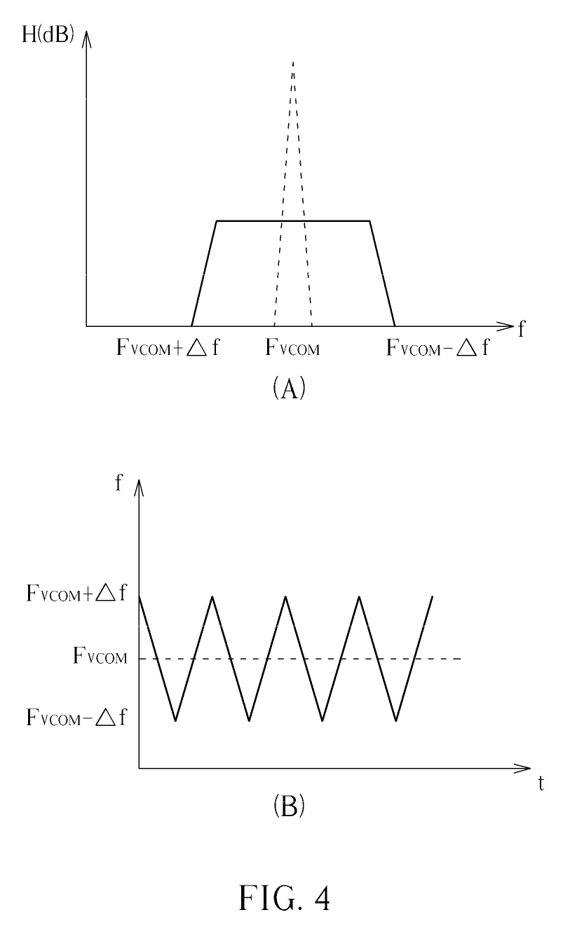

Please refer to FIG. 4. FIG. 4 is a diagram illustrating the time domain and the frequency domain of the common signal V_{COM}. As shown in FIG. 4, the part (A) represents the time domain of the common signal V_{COM}, where the horizontal axis represents the time and the vertical axis represents the frequency; the part (B) represents the frequency domain of the common signal V_{COM}, where the horizontal axis represents the frequency and the vertical axis represents the amplitude (in dB); F_{VCOM}, F_{VCOM}+Δf and F_{VCOM}−Δf represent different frequencies of the common signal. As shown in the time domain of the common signal V_{COM}, the frequency of the common signal V_{COM} is modulated in the frequency range between the frequencies F_{VCOM}+Δf and F_{VCOM}−Δf. Therefore, as shown in the frequency domain of the common signal V_{COM}, the energy of the acoustic noise is distributed in the frequency range between frequencies F_{VCOM}+Δf and F_{VCOM}−Δf. In the present invention the modulation circuit 34 is added to the driving circuit 30 of the LCD, for modulating the frequency of the common signal V_{COM} generated from the common signal generator 32 so the common signal V_{COM} is modulated from the fixed frequency F_{VCOM}, to a frequency swings in the frequency range F_{VCOM}±Δf. Therefore, in the frequency domain, the energy of the acoustic noise is distributed in the frequency range F_{VCOM}±Δf, effectively reducing the energy accumulated at the fixed frequency F_{VCOM} (as indicated by the dotted line).

In conclusion, under the conventional LCD structure, the present invention utilizes the modulated frequency of the common signal to alter the resonance of the LCD, for decreasing the acoustic noise generated from the conventional single frequency. The driving circuit of the LCD of the present invention comprises a common signal generator and a modulation circuit. The common signal generator generates a common signal. The modulation circuit is electrically connected to the common signal generator, for modulating the frequency of the common signal. The modulation circuit can generate a first frequency, a second frequency, and a third frequency. The common signal generator generates a swing common signal according to the first frequency, and modulates the frequency of the common signal in the frequency range between the second frequency and the third frequency. Therefore, the driving circuit of the LCD of the present invention can improve the acoustic noise caused by the frequency of the common signal.

Those skilled in the art will readily observe that numerous modifications and alterations of the device and method may be made while retaining the teachings of the invention.

What is claimed is:

1. A method for modulating a common signal of the LCD, the method comprising:
providing a first frequency;
generating a swing common signal according to the first frequency;
generating a second frequency and a third frequency according to the first frequency; and
modulating a frequency of the common signal in a frequency range between the second frequency and the third frequency.

2. The method of claim 1, wherein generating the swing common signal according to the first frequency comprises:
providing a high level voltage and a low level voltage; and
generating the swing common signal between the high level voltage and the low level voltage according to the first frequency.

3. The method of claim 1, wherein generating the second frequency and the third frequency according to the first frequency comprises:
generating the second frequency that is higher than the first frequency; and
generating the third frequency that is lower than the first frequency.

4. The method of claim 1, wherein modulating the frequency of the common signal in the frequency range between the second frequency and the third frequency comprises:
outputting the common signal of the third frequency in a first duration;
outputting the common signal of the first frequency in a second duration; and
outputting the common signal of the second frequency in a third duration.

5. The method of claim 1, further comprising:
adjusting a display signal of the LCD according to the modulated common signal.

6. A driving circuit of an LCD, comprising:
a common signal generator, for generating a swing common signal according to a high level voltage and a low level voltage; and
a modulation circuit, electrically connected to the common signal generator, for modulating frequency of the common signal.

7. The driving circuit of claim 6, wherein the LCD outputs a display signal according to the modulated common signal.

8. The driving circuit of claim 6, wherein the common signal generated by the common signal generator comprises a first frequency.

9. The driving circuit of claim 8, wherein the modulation circuit is utilized to generate a second frequency that is higher than the first frequency, and a third frequency that is lower than the first frequency.

10. The driving circuit of claim 9, wherein the modulation circuit is utilized to modulate frequency of the common signal in a frequency range between the second frequency and the third frequency.
